(19) United States
(12) Patent Application Publication
(10) Pub. No.: US 2008/0051524 A1
(43) Pub. Date: Feb. 28, 2008

(54) Epoxy-Based Compositions Having Improved Impact Resistance

(75) Inventors: Qing Ji, El Monte, CA (US); Qiaohong Huang, Mission Viejo, CA (US); Renzhe Zhao, Chino Hills, CA (US); Michael Todd, Anaheim Hills, CA (US)

Correspondence Address: LOCTITE CORPORATION, 1001 TROUT BROOK CROSSING, ROCKY HILL, CT, 06067, US

(73) Assignee: HENKEL CORPORATION

(21) Appl. No.: 11/467,610

(22) Filed: Aug. 28, 2006

(51) Int. Cl. C08L 63/00; C08L 83/04; H01L 21/56; B32B 27/38

(52) U.S. Cl. 525/476; 428/413; 438/127

(57) ABSTRACT

This invention relates to epoxy-based compositions useful as adhesives and sealants, and more particularly to underfill sealant, compositions with improved impact resistance.

### BACKGROUND OF THE INVENTION

1. Field of the Invention

This invention relates to epoxy-based compositions useful as adhesives and sealants, and more particularly to underfill sealant compositions with improved impact resistance.

2. Brief Description of Related Technology

Numerous compositions are described for making and using a wide variety of epoxy-based compositions and other resins and additives in an effort to improve the expansion, impact resistance and other key properties of adhesives useful in adhering, filling and making composite structures. For example, certain U.S. patent documents which describe components for the formulation of adhesive compositions and the use of such compositions to adhere various substrates to each other include U.S. Pat. Nos. 5,290,857, 5,686,509, 5,334,654, 6,015,865, 5,278,257, 6,884,854, and 6,776,869 and U.S. Patent Application Publication No. 2005-0022929.

U.S. Pat. No. 7,084,492 was recently issued to Intel Corporation, and is directed to underfill and mold compounds including siloxane-based aromatic diamines. These underfill and mold compounds seem to be based on reaction products of such diamines with epoxy resins, where representative examples of the diamines are given at column 3, line 45 to column 5, line 20 thereof.

Nevertheless, there remains significant room in the field for epoxy-based compositions having improved impact resistance.

### SUMMARY OF THE INVENTION

The present invention provides epoxy-based compositions having improved impact resistance, which include an epoxy component, an epoxy-functionalized silicone component, a latent curing agent capable of being activated by heat, and rubber particles having a core-shell structure. The epoxy-functionalized silicone component acts as a toughening agent together with the rubber particles having a core-shell structure in the cured reaction product, a heat-activated latent curing agent, where when cured the composition demonstrates a K_{IC} greater than about 2.5.

In practice, the inventive epoxy-based compositions are useful as electronic materials for semiconductor packaging and assembly applications. For instance, the inventive compositions are particularly useful as underfill sealants.

### BRIEF DESCRIPTION OF THE FIGURES

FIG. 1 depicts a cross-sectional view showing an example of a semiconductor chip which has been mounted onto a circuit board, and the underfilling sealed with a composition of the present invention.

FIG. 2 depicts a cross-sectional view showing an example of a semiconductor device in which a composition of the present invention is used as an underfill sealant.

### DETAILED DESCRIPTION OF THE INVENTION

### Epoxy Resins

In general, a large number of polyepoxides having at least about two 1,2-epoxy groups per molecule are suitable as epoxy resins for the compositions of this invention. The polyepoxides may be saturated, unsaturated, cyclic or acyclic, aliphatic, alicyclic, aromatic or heterocyclic polyepoxide compounds. Examples of suitable polyepoxides include the polyglycidyl ethers, which are prepared by reaction of epichlorohydrin or epibromohydrin with a polyphenol the presence of alkali. Suitable polyphenols therefor are, for example, resorcinol, pyrocatechol, hydroquinone, bisphenol A (bis(4-hydroxyphenyl)-2,2-propane), bisphenol F (bis(4-hydroxyphenyl)methane), bisphenol S, biphenol, bis(4-hydroxyphenyl)-1,1-isobutane, 4,4′-diydroxybenzophenone, bis(4-hydroxyphenyl)-1,1-ethane, and 1,5-hydroxynaphthalene. Other suitable polyphenols as the basis for the polyglycidyl ethers are the known condensation products of phenol and formaldehyde or acetaldehyde of the novolak resin-type.

Other polyepoxides that are in principle suitable for use herein are the polyglycidyl ethers of polyalcohols or diamines. Such polyglycidyl ethers are derived from polyalcohols, such as ethylene glycol, diethylene glycol, triethylene glycol, 1,2-propylene glycol, 1,4-butylene glycol, triethylene glycol, 1,5-pentanediol, 1,6-hexanediol or trimethylolpropane.

Still other polyepoxides are polyglycidyl esters of polycarboxylic acids, for example, reaction products of glycidol or epichlorohydrin with aliphatic or aromatic polycarboxylic acids, such as oxalic acid, succinic acid, glutaric acid, terephthalic acid or a dimeric fatty acid.

And still other epoxides are derived from the epoxidation products of olefinically-unsaturated cycloaliphatic compounds or from natural oils and fats.

Particular preference is given to the liquid epoxy resins derived by reaction of bisphenol A or bisphenol F and epichlorohydrin. The epoxy resins that are liquid at room temperature generally have epoxy equivalent weights of from 150 to about 480.

Typically, the composition may contain from about 25 to about 55 weight percent (in one embodiment, from about 30 to about 50 weight percent) of epoxy resin.

The composition may include as at least a portion of the epoxy component a reactive diluent such as a mono-epoxide (e.g., monoglycidyl ethers of alkyl- and alkenyl-substituted phenols). Typically, the composition contains from about 0.5 to about 10 percent by weight reactive diluent.

### Epoxy-Functionalized Silicones

Many epoxy-functionalized silicone materials are useful in connection with the present invention, provided of course that the identity and/or amount of such materials lend compatibility to the composition.

One such example is the glycidoxy functional silane polymer available commercially from Wacker Silicone under the tradename SILRES HP1000. SILRES HP1000 is promoted for use as a binder to increase UV resistance and corrosion resistance of two component coating formulations.

SILRES HP1000 is reported by Wacker as having a weight per epoxy between 330-350 grams of polymer per moles of epoxy. This property reports Wacker makes it highly reactive with nucleophiles such as Phosphoric acid, acid functional acrylics, amine and amino functional curing agents.

Typically, the composition may contain from about 0.5 to about 20 weight percent (in one embodiment, from about 5 to about 10 weight percent) of the epoxy-functionalized silicone.

### Core-Shell Rubber Particles

Rubber particles having a core-shell structure are an additional component of the compositions of the present invention. Such particles generally have a core comprised of a polymeric material having elastomeric or rubbery properties (i.e., a glass transition temperature less than about 0° C., e.g., less than about −30° C.) surrounded by a shell comprised of a non-elastomeric polymeric material (i.e., a thermoplastic or thermoset/crosslinked polymer having a glass transition temperature greater than ambient temperatures, e.g., greater than about 50° C.). For example, the core may be comprised of a diene homopolymer or copolymer (for example, a homopolymer of butadiene or isoprene, a copolymer of butadiene or isoprene with one or more ethylenically unsaturated monomers such as vinyl aromatic monomers, (meth)acrylonitrile, (meth)acrylates, or the like) while the shell may be comprised of a polymer or copolymer of one or more monomers such as (meth)acrylates (e.g., methyl methacrylate), vinyl aromatic monomers (e.g., styrene), vinyl cyanides (e.g., acrylonitrile), unsaturated acids and anhydrides (e.g., acrylic acid), (meth)acrylamides, and the like having a suitably high glass transition temperature. Other rubbery polymers may also be suitably be used for the core, including polybutylacrylate or polysiloxane elastomer (e.g., polydimethylsiloxane, particularly crosslinked polydimethylsiloxane). The rubber particle may be comprised of more than two layers (e.g., a central core of one rubbery material may be surrounded by a second core of a different rubbery material or the rubbery core may be surrounded by two shells of different composition or the rubber particle may have the structure soft core, hard shell, soft shell, hard shell). In one embodiment of the invention, the rubber particles used are comprised of a core and at least two concentric shells having different chemical compositions and/or properties. Either the core or the shell or both the core and the shell may be crosslinked (e.g., ionically or covalently). The shell may be grafted onto the core. The polymer comprising the shell may bear one or more different types of functional groups (e.g., epoxy groups) that are capable of interacting with other components of the compositions of the present invention.

Typically, the core will comprise from about 50 to about 95 percent by weight of the rubber particles while the shell will comprise from about 5 to about 50 percent by weight of the rubber particles.

Preferably, the rubber particles are relatively small in size. For example, the average particle size may be from about 0.03 to about 2 microns or from about 0.05 to about 1 micron. In certain embodiment of the invention, the rubber particles have an average diameter of less than about 500 nm. In other embodiments, the average particle size is less than about 200 nm. For example, the core-shell rubber particles may have an average diameter within the range of from about 25 to about 200 nm.

Methods of preparing rubber particles having a core-shell structure are well-known in the art and are described, for example, in U.S. Pat. Nos. 4,419,496, 4,778,851, 5,981,659, 6,111,015, 6,147,142 and 6,180,693, each of which being expressly incorporated herein by reference in its entirety.

Rubber particles having a core-shell structure may be prepared as a masterbatch where the rubber particles are dispersed in one or more epoxy resins such as a diglycidyl ether of bisphenol A. For example, the rubber particles typically are prepared as aqueous dispersions or emulsions. Such dispersions or emulsions may be combined with the desired epoxy resin or mixture of epoxy resins and the water and other volatile substances removed by distillation or the like. One method of preparing such masterbatches is described in more detail in International Patent Publication No. WO 2004/108825, incorporated herein by reference in its entirety. For example, an aqueous latex of rubber particles may be brought into contact with an organic medium having partial solubility in water and then with another organic medium having lower partial solubility in water than the first organic medium to separate the water and to provide a dispersion of the rubber particles in the second organic medium. This dispersion may then be mixed with the desired epoxy resin(s) and volatile substances removed by distillation or the like to provide the masterbatch.

Particularly suitable dispersions of rubber particles having a core-shell structure in an epoxy resin matrix are available from Kaneka Corporation. For instance, KANEKA MX-120, a masterbatch of 25 weight percent nano-sized core-shell rubber (with the core being predominately a polybutadiene/styrene blend) in a matrix of bisphenol A diglycidyl ether epoxy resin, is a particularly desirable core shell rubber particle for use herein. Other useful core shell rubber particles include KANEKA MX-156.

For instance, the core of such rubber particles from Kaneka may be formed predominantly from feed stocks of polybutadiene, polyacrylate, polybutadiene/acrylonitrile mixture, polyols and/or polysiloxanes or any other monomers that give a low glass transition temperature. The outer shells may be formed predominantly from feed stocks of polymethylmethacrylate, polystyrene or polyvinyl chloride or any other monomers that give a higher glass transition temperature.

The core shell rubbers may have a particle size in the range of 0.07 to 10 um, such as 0.1 to 5 um.

The core shell rubber made in this way may be dispersed in an epoxy matrix or a phenolic matrix. Examples of epoxy matrices include the diglycidyl ethers of bisphenol A, F or S, or biphenol, novalac epoxies, and cycloaliphatic epoxies. Examples of phenolic resins include bisphenol-A based phenoxies.

The core shell rubber dispersion may be present in the epoxy or phenolic matrix in an amount in the range of about 5 to about 50% by weight, with about 15 to about 25 percent by weight being desirable based on viscosity considerations.

In the inventive formulations, use of these core shell rubbers allows for toughening to occur in the formulation, irrespective of the temperatures used to cure the formulation. That is, because of the two phase separation Inherent in the formulation due to the core shell rubber—as contrasted for instance with a liquid rubber that is miscible or partially miscible or even immiscible in the formulation and can solidify at temperatures different than those used to cure the formulation—there is a minimum disruption of the matrix properties, as the phase separation in the formulation is often observed to be substantially uniform in nature.

In addition, predictable toughening—in terms of temperature neutrality toward cure—may be achieved because of the substantial uniform dispersion.

The core shell rubber, may be present in the epoxy or phenolic dispersion in an amount in the range of about 5 to about 50 percent by weight with about 15 to about 25 percent by weight being desirable At the higher ranges of this core shell rubber content, viscosity increases may be observed in the dispersion in relatively short periods of time and agglomeration, settling and gelling may also be observed in the dispersions.

In the inventive formulations, use of these core shell rubbers allows for toughening to occur in the formulation as it cures, irrespective of the temperatures used to cure the formulation. That is, because of the two phase separation inherent in the formulation due to the core shell rubber—as contrasted for instance with a liquid rubber that is miscible in the formulation and can solidify at temperatures different than those used to cure the formulation—there is a minimum disruption of the matrix properties, as the two phase separation in the formulation is often observed to be substantially uniform in nature.

In addition, predictable toughening—in terms of temperature neutrality toward cure—may be achieved because of the substantial uniform dispersion.

Many of the core-shell rubber structures available from Kaneka are believed to have a core made from a copolymer of (meth)acrylate-butadiene-styrene, where the butadiene is the primary component in the phase separated particles, dispersed in epoxy resins.

Other commercially available masterbatches of core-shell rubber particles dispersed in epoxy resins include GENIOPERL M23A (a dispersion of 30 weight percent core-shell particles in an aromatic epoxy resin based on bisphenol A diglycidyl ether; the core-shell particles have an average diameter of ca. 100 nm and contain a crosslinked silicone elastomer core onto which an epoxy-functional acrylate copolymer has been grafted); the silicone elastomer core represents about 65 weight percent of the core-shell particle), available from Wacker Chemie GmbH.

Typically, the composition may contain from about 5 to about 25 weight percent (in one embodiment, from about 8 to about 20 weight percent) rubber particles having a core-shell structure.

### Adhesion Promoters

Adhesion promoters such as the silanes, glycidyl trimethoxysilane (commercially available from OSI under the trade designation A-187) or gamma-amino propyl triethoxysilane (commercially available from OSI under the trade designation A-1100), may be used in the present invent on, as well.

Typically, the composition may contain from about 0.5 to about 10 weight percent of such adhesion promoters.

### Curing Agents

Since the compositions of the present invention are preferably one-part or single-component compositions and are to be cured at elevated temperature, they also contain one or more curing agents capable of accomplishing cross-linking or curing of certain of the adhesive components when the adhesive is heated to a temperature well in excess of room temperature. That is, the hardener is activated by heating. The curing agent may function in a catalytic manner or participate directly in the curing process by reaction with one or more of the components of the inventive composition.

The curing agent component may be selected from nitrogen-containing compounds such as amine compounds, amide compounds, imidazole compounds, guanidine compounds, urea compounds and derivatives and combinations thereof.

For instance, the amine compounds may be selected from, aliphatic polyamines, aromatic polyamines, alicyclic polyamines and combinations thereof.

The amine compounds may be selected from diethylenetriamine, triethylenetetramine, diethylaminopropylamine, xylenediamine, diaminodiphenylamine, isophoronediamine, menthenediamine and combinations thereof.

In addition, modified amine compounds, may be used, which include epoxy amine additives formed by the addition of an amine compound to an epoxy compound, for instance novolac-type resin modified through reaction with aliphatic amines.

The imidazole compounds may be selected from imidazole, isoimidazole, alkyl-substituted imidazoles, and combinations thereof. More specifically, the imidazole compounds are selected from 2-methyl imidazole, 2-ethyl-4-methylimidazole, 2,4-dimethylimidazole, butylimidazole, 2-heptadecenyl-4-methylimidazole, 2-undecenylimidazole, 1-vinyl-2-methylimidazole, 2-n-heptadecylimidazole, 2-undecylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-guanaminoethyl-2-methylimidazole and addition products of an imidazole and trimellitic acid, 2-n-heptadecyl-4-methylimidazole, aryl-substituted imidazoles, phenylimidazole, benzylimidazole, 2-methyl-4,5-diphenylimidazole, 2,3,5-triphenylimidazole, 2-styrylimidazole, 1-(dodecyl benzyl)-2-methylimidazole, 2-(2-hydroxyl-4-t-butylphenyl)-4,5-diphenylimidazole, 2-(2-methoxyphenyl)-4,5-diphenylimidazole, 2-(3-hydroxyphenyl)-4,5-diphenylimidazole, 2-(p-dimethylaminophenyl)-4,5-diphenylimidazole, 2-(2-hydroxyphenyl)-4,5-diphenylimidazole, di(4,5-diphenyl-2-imidazole)-benzene-1,4, 2-naphthyl-4,5-diphenylimidazole, 1-benzyl-2-methylimidazole, 2-p-methoxystyrylimidazole, and combinations thereof.

Modified imidazole compounds may be used as well, which include imidazole adducts formed by the addition of an imidazole compound to an epoxy compound.

Guanidines, substituted guanidines, substituted ureas, melamine resins, guanamine derivatives, cyclic tertiary amines, aromatic amines and/or mixtures thereof. The hardeners may be involved stoichiometrically in the hardening reaction; they may, however, also be catalytically active. Examples of substituted guanidines are methylguanidine, dimethylguanidine, trimethylguanidine, tetramethylguanidine, methylisobiguanidine, dimethylisobiguanidine, tetramethylisobiguanidine, hexamethylisobiguanidine, heptamethylisobiguanidine and cyanoguamidine (dicyandiamide). Representative guanamine derivatives include alkylated benzoguanamine resins, benzoguanamine resins and methoxymethylethoxymethylbenzoguanamine.

In addition to or instead of the above-mentioned hardeners, catalytically-active substituted ureas may be used. They are especially p-chlorophenyl-N,N-dimethylurea (monuron), 3-phenyl-11-dimethylurea (fenuron) or 3,4-dichlorophenyl-N,N-dimethylurea (diuron). In principle, catalytically active tertiary acryl- or alkyl-amines, such as benzyldimethylamine, tris(dimethylamino)phenol, piperidine or piperidine derivatives, may also be used, but they are in many cases too highly soluble in the adhesive system, so that usable storage stability of the single-component system is not achieved. Various imidazole derivatives, preferably solid imidazole derivatives, may also be used as catalytically-active accelerators. Examples which may be mentioned are 2-ethyl-2-methylimidazole, N-butylimidazole, benzimidazole and N—C₁ to C₁₂-alkylimidazoles or N-arylimidazoles. Particular preference is given to the use of a combination of hardener and accelerator in the form of so-called accelerated dicyandiamides in finely ground form. The separate addition of catalytically-active accelerators to the epoxy hardening system is thus not necessary.

The amount of curing agent utilized will depend upon a number of factors, including whether the curing agent acts as a catalyst or participates directly in crosslinking of the composition, the concentration of epoxy groups and other reactive groups in the composition, the desired curing rate and so forth. Typically, the composition contains from about 0.5 to about 8 weight percent curing agent(s).

### Fillers

The inventive compositions may also contain known fillers such as the various ground or precipitated chalks, quartz powder, alumina, kaolin, dolomite, carbon fibers, glass fibers, polymeric fibers, titanium dioxide, fused silica, fused silica, precipitated silica, carbon black, calcium oxide, calcium magnesium carbonates, barite and, especially, silicate-like fillers of the aluminum magnesium calcium silicate type, for example wollastonite and chlorite. Typically, the compositions of the present invention may contain from about 0.5 to about 10 percent by weight of fillers.

In another embodiment, spacer elements are present in the composition. Spacers contemplated for use in the practice of the present invention are substantially spherical, and typically have a particle size in the range of about 0.02 mils up to about 25 mils. Preferably, the spacers have a particle size in the range of about 0.1 mils up to about 15 mils. As employed herein, “mil” is a unit of measure equal to 1/1000 of an inch. Before, during, and after curing of invention adhesive formulations, the integrity of the spacers is maintained, i.e., the size and shape of the spacers remains substantially constant before, during, and after cure. For example, the spacers preferably do not swell, soften, or dissolve upon incorporation into the adhesive composition. Additionally, spacers contemplated for use in the practice of the present invention are preferably hydrophobic.

Spacers contemplated for use in the practice of the present invention optionally contain reactive moieties which allow the spacers to crosslink with other components in the adhesive composition. As employed herein, “reactive moiety” refers to a functional group, which reacts with at least one other component in the composition.

Two general types of collapsible spacer elements may be used, those being spacers constructed from metal on the one hand and plastic on the other. Suitable metals for use as collapsible spacers include relatively low melting point alloys, such as Wood's metal and other solder-like alloys, having a relatively low melting temperature (Tₘ). The plastic may be categorized as non-charring, solvent-resistant, depolymerizable polymers having a relatively low softening or glass transition temperature (T_{g}), such as collapsible spheroids made from polypropylene carbonate and polyalkyl methacrylate resins.

The compositions according to the present invention may also contain other additives, such as plasticizers, reactive and/or ton-reactive diluents, flow control agents, coupling agents (e.g., silanes), adhesion promoters, wetting agents, tackifiers, flame retardants, thixotropic and/or rheology control agents, ageing and/or corrosion inhibitors, stabilizers and/or coloring pigments. Depending on the requirements made of the adhesive application with respect to its processing properties, its flexibility, the required rigidifying action and the adhesive bond to the substrates, the relative proportions of the individual components may vary within comparatively wide limits.

The thermosetting resin compositions according to the present invention are capable of penetrating into the space between the circuit board and the semiconductor device. These inventive compositions also demonstrate a reduced viscosity, at least under elevated temperature conditions, and thus are capable of penetrating into that space. It is desirable to prepare the thermosetting resin composition by selecting the types and proportions of various ingredients to reach a viscosity at 25° C. of 10,000 mPa·s or less, such as 3,000-4,000 mPa·s, so as to improve its ability to penetrate into the space (e.g., of 50 to 500 μm) between the circuit board and the semiconductor device.

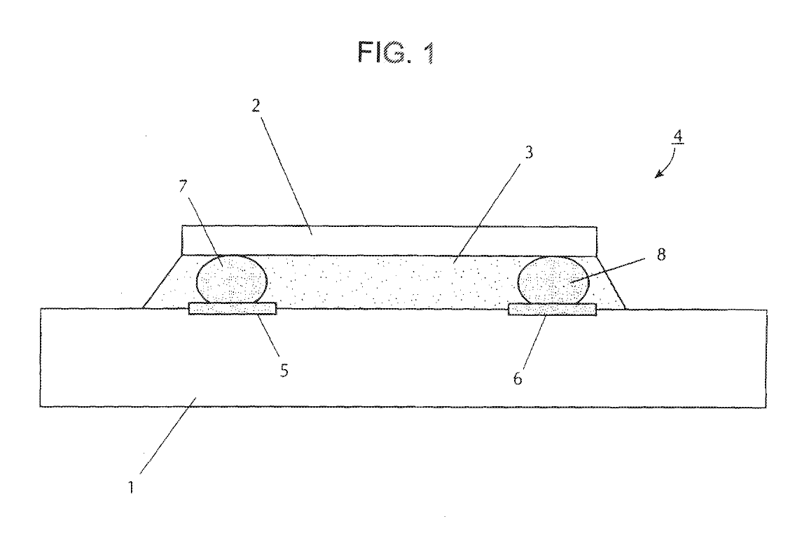

Reference to FIG. 1 shows an example of a semiconductor chip mounted to a circuit board as a flip chip assembly, in which the thermosetting resin composition of the present invention is used as an underfill sealant.

The semiconductor device 4 is one formed by connecting a semiconductor chip (so-called bare chip) 2, such as LSI, to a circuit board 1 and sealing the space therebetween suitably with thermosetting resin composition 3. The semiconductor chip 2 is mounted at a predetermined position of the circuit board 1, where bonding pads 5 and 6 are used to electrically connect through a suitable connection means, such as solder 7 and 8, the semiconductor chip 2 to the circuit board 1. In order to improve reliability, the space between semiconductor chip 2 and circuit board 1 is sealed with the cured product of a thermosetting resin composition 3. The cured product of the thermosetting resin composition 3 need not completely fill the space between semiconductor chip 2 and circuit board 1, but may fill it to such an extent as to relieve stresses caused by thermal cycling.

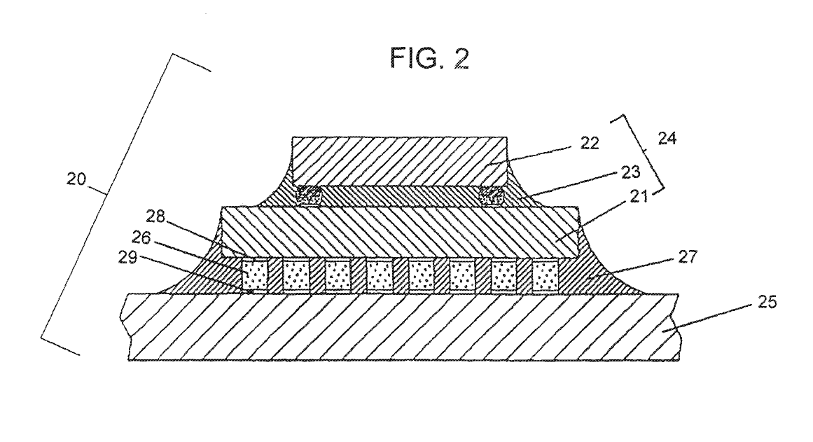

As regards semiconductor device mounting structures, such as a LSP, reference to FIG. 2 shows a semiconductor device mounting structure in which semiconductor device 24 is mounted to a circuit board 25 and sealing the space therebetween suitably with a thermosetting resin composition, such as composition 23. This semiconductor device 24 is mounted at a predetermined position on the circuit board 25 and electrodes 26 are electrically connected by a suitable electrical connection means 28 and 29, such as bonding pads. The space between the semiconductor chip 22 and the carrier substrate 21 which forms the semiconductor device 24 is also sealed with a thermosetting resin composition 23 and then cured. The cured product of the thermosetting resin composition should completely fill that space.

No particular limitation is placed on the means for electrically connecting the semiconductor chip to the carrier substrate, and there may be employed connection by a high-melting solder or electrically (or anisotropically) conductive adhesive, wire bonding, and the like. In order to facilitate connections, the electrodes may be formed as bumps. Carrier substrates may be constructed from ceramic substrates made of Al₂O₃, SiN₃ and mullite Al₂O₃—SiO₂); substrates or tapes made of heat-resistant resins such as polyimides; glass-reinforced epoxy, ABS and phenolic substrates which are also used commonly as circuit boards; and the like. The semiconductor devices that can be used in the present invention include CSPs, BGAs, and LCAs.

No particular limitation is placed on the type of circuit board used in the present invention, and there may be used any of various common circuit boards such as glass-reinforced epoxy, ABS and phenolic boards.

Next, the mounting process is describes below. Initially, cream solder is printed at the necessary positions of a circuit board and suitably dried to expel the solvent. Then, a semiconductor device is mounted in conformity with the pattern on the circuit board. This circuit board is passed through a reflowing furnace to melt the solder and thereby solder the semiconductor device. The electrical connection between the semiconductor device and the circuit board is not limited to the use of cream solder, but may be made by use of solder balls Alternatively, this connection may also be made through an electrically conductive adhesive or an anisotropically conductive adhesive. Moreover, cream solder or the like may be applied or formed on either the circuit board or the semiconductor device. In order to facilitate subsequent repairs, the solder, electrically or anisotropically conductive adhesive used should be chosen bearing in mind its melting point, bond strength and the like.

After the semiconductor device is electrically connected to the circuit board in this manner, the resulting structure should ordinarily be subjected to a continuity test or the like. After passing such test, the semiconductor device may be fixed thereto with a resin composition. In this way, in the event of a failure, it is easier to remove the semiconductor device before fixing it with the resin composition.

Then, using a suitable application means such as dispenser, a composition is applied to the periphery of the semiconductor device. When this composition is applied to the semiconductor device, it penetrates into the space between the circuit board and the carrier substrate of the semiconductor device by capillary action.

Next, the composition may be cured by exposure to the application of heat. During the early stage of this heating, the composition shows a significant reduction in viscosity and hence an increase in fluidity, so that it more easily penetrates into the space between the circuit board and the semiconductor device. Moreover, by providing the circuit board with suitable venting holes, the composition is allowed to penetrate fully into the entire space between the circuit board and the semiconductor device.

The amount of composition applied should be suitably adjusted so as to fill the space between the circuit board and the semiconductor device almost completely.

When the above-described thermosetting resin composition is used, it is usually cured by heating at a temperature of about 80° C. to about 150° C. for a period of time of about 5 to about 60 minutes. Thus, the present invention can employ relatively low-temperature and short-time curing conditions and hence achieve very good productivity. The semiconductor device mounting structure illustrated in FIG. 1 is completed in this manner.

The inventive compositions may be used also as casting resins in the electrical or electronics industry or as die attach adhesives in semiconductor packaging applications for bonding die to printed circuit boards. Further possible applications for the compositions are as matrix materials for composites, such as fiber-reinforced composites.

### EXAMPLES

Five samples were prepared, the type, identity and amount of the composition of which are shown in Table 1, to evaluate the extent to which the combination of the core shell rubber toughener and the epoxy-functionalized siloxane changed the impact toughness of a cured epoxy composition, contrasted to compositions with either and neither of such materials.

TABLE 1

| Components | | Sample Nos./Amt. (wt %) | | | | |
|---|---|---|---|---|---|---|
| Type | Identity | 1 | 2 | 3 | 4 | 5 |
| Epoxy | Bisphenol-A/ | 20.29 | 22.46 | 11.95 | 18.3 | 26.22 |
| | Bisphenol-F/ | | | | | |
| | Reactive Diluent* | | | | | |
| Curing Agent | Liquid aromatic | 10.51 | 10.84 | 6.35 | 9.8 | 12.32 |
| | amine | | | | | |
| Core Shell | MX-120LV** | 10.00 | 10.00 | — | — | — |
| Rubber | | | | | | |
| Toughener | STAPHYLOID AC- | — | — | — | — | 10.00 |
| | 3335*** | | | | | |
| Filler | Silica | 55.00 | 55.00 | 70.00 | 70.00 | 50.00 |
| Epoxy | HP-1000 | 2.50 | — | 10.00 | — | — |
| Functionalized | | | | | | |
| Siloxane | | | | | | |
| Additives | Silane Adhesion | 1.7 | 1.7 | 1.7 | 1.9 | 1.46 |
| | Promoter | | | | | |
| | Surfactant | | | | | |
| | Defoamer | | | | | |
| | Materials | | | | | |
| | Black Pigment | | | | | |

*polypropylene glycol glydcidyl ether available commercially from Hunstman Advanced Materials Americas Inc. under the trade name ARALDITE DY 3601 or from Resolution Performance Products under the trade name HELOXY Modifier 68
**available as a nano scale dispersion in epoxy resin from Kaneka Corporation
***alkylacrylate-alkylmethacrylate copolymer

Because of the different filler content of the five samples, the amount of the various components changed to some degree. Ordinarily, it is believed that the core shell rubber content should be 5% to 10%, while the epoxy functionaiized silicone should be from 2% to 20%.

As can be seen in Table 2, the combination of the core shell rubber toughener and the epoxy-functionalized siloxane provides an improvement of impact toughness in epoxy compositions of at least 18% over epoxy compositions with only one of such materials or without either of sued materials. Thus, of the five samples illustrated, only Sample No. 1 is seen to provide a K_{IC} of greater than 2.5.

TABLE 2

| Physical | Sample Nos. | | | | |
|---|---|---|---|---|---|
| Properties | 1 | 2 | 3 | 4 | 5 |
| K_{1c} (Mpa * m ½) | 2.926 | 2.384 | 2.2 | 1.9 | 1.8 |

What is claimed is:

1. A curable composition comprising:
A) a epoxy component;
B) an epoxy-functionalized silicone;
C) rubber particles having a nano-sized core-shell structure, with the core being predominately a polybutadiene/styrene blend; and
D) a heat-activated latent curing agent, wherein when cured the composition demonstrates a K_{IC} greater than about 2.5.

2. The composition of claim 1 wherein said rubber particles have a shell comprised of an alkyl (meth)acrylate homopolymer or copolymer.

3. The composition of claim 1 wherein said rubber particles have an average diameter of from about 0.05 to about 1 micron.

4. The composition of claim 1, wherein the epoxy component comprises at least one reactive diluent which is a mono-epoxide.

5. The composition of claim 1, wherein the epoxy-functionalized silicone is present in an amount from about 0.5 to about 20 weight percent.

6. The composition of claim 1, further comprising an inorganic filler component.

7. The composition of claim 2, wherein the coreactant diluent is glycidyl neodecanoate.

8. The composition of claim 4, wherein the inorganic finer component is a member selected from the group consisting of silica, aluminum oxide, silicon nitride, aluminum nitride, silica-coated aluminum nitride, boron nitride and combinations thereof.

9. The composition of claim 1, capable of sealing underfilling between a semiconductor device including a semiconductor chip mounted on a carrier substrate and a circuit board to which said semiconductor device is electrically connected, or a semiconductor chip and a circuit board to which said semiconductor chip is electrically connected, reaction products of which are capable of softening and losing adhesiveness.

10. Reaction products of compositions in accordance with claim 1.

11. The composition of claim 2, wherein the curing agent component is a member selected from the group consisting o amine compounds, amide compounds, imidazole compounds, and derivatives and combinations thereof.

12. The composition of claim 11, wherein the amine compounds are selected from the group consisting of aliphatic polyamines, aromatic polyamines, alicyclic polyamines and combinations thereof.

13. The composition of claim 11, wherein the amine compounds are selected from the group consisting of diethylenetriamine, triethylenetetramine, diethylaminopropylamine, xylenediamine, diaminodiphenylamine, isophoronediamine, menthenediamine and combinations thereof.

14. The composition of claim 11 wherein the imidazole compounds are selected from imidazole, isoimidazole, alkyl-substituted imidazoles, and combinations thereof.

15. The composition of claim 11, wherein the imidazole compounds are selected from 2-methyl imidazole, 2-ethyl-4-methylimidazole, 2,4-dimethylimidazole, butylimidazole, 2-heptadecenyl-4-methylimidazole, 2-undecenylimidazole, 1-vinyl-2-methylimidazole, 2-n-heptadecylimidazole, 2-undecylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-uindecylimidazole, 1-cyanoethyl-2-phenylimidazole, 1-guanaminoethyl-2-methylimidazole and addition products of an imidazole and trimellitic acid, 2-n-heptadecyl-4-methylimidazole, aryl-substituted imidazoles, phenylimidazole, benzylimidazole, 2-methyl-4,5-diphenylimidazole, 2,3,5-triphenylimidazole, 2-styrylimidazole, 1-(dodecyl benzyl)-2-methylimidazole, 2-(2-hydroxy-4-t-butylphenyl)-4,5-diphenylimidazole, 2-(2-methoxyphenyl)-4,5-diphenylimidazole, 2-(3-hydroxyphenyl)-4,5-diphenylimidazole, 2-(p-dimethylaminophenyl)-4,5-diphenylimidazole, 2-(2-hydroxyphenyl)-4,5-diphenylimidazole, di(4,5-diphenyl-2-imidazole)-benzene-1,4, 2-naphthyl-4,5-diphenylimidazole, 1-benzyl-2-methylimidazole, 2-p-methoxystyrylimidazole, and combinations thereof.

16. The composition of claim 11, wherein the modified amine compounds include epoxy amine additives formed by the addition of an amine compound to an epoxy compound.

17. The composition of claim 11, wherein the modified amine compounds are novolac-type resin modified through reaction with aliphatic amines.

18. The composition of claim 11, wherein the modified imidazole compounds include imidazole adducts formed by the addition of an imidazole compound to an epoxy compound.

19. An electronic device comprising a semiconductor device and a circuit board to which said semiconductor device is electrically connected or a semiconductor chip and a circuit board to which said semiconductor chip is electrically connected, assembled using a thermosetting resin composition according to claim 1 as an underfill sealant between the semiconductor device and the circuit board or the semiconductor chip and the circuit board, respectively, wherein reaction products of the composition are capable of softening and losing their adhesiveness under exposure to temperature conditions in excess of those used to cure the composition.

20. A method of sealing underfilling between a semiconductor device including a semiconductor chip mounted on a carrier substrate and a circuit board to which said semiconductor device is electrically connected or a semiconductor chip and a circuit board to which said semiconductor chip is electrically connected, the steps of which comprise:
(a) dispensing into the underfilling between the semiconductor device and the circuit board or the semiconductor chip and the circuit board a composition in accordance with claim 1; and
(b) exposing the composition as so dispensed to conditions appropriate to cause the composition to form a reaction product.
